(19) United States
(12) Patent Application Publication
(10) Pub. No.: US 2014/0224296 A1
(43) Pub. Date: Aug. 14, 2014

(54) NANOWIRE COMPOSITE FOR THERMOELECTRICS

(71) Applicant: THE REGENTS OF THE UNIVERSITY OF CALIFORNIA, Oakland, CA (US)

(72) Inventors: Nobuhiko Kobayashi, Sunnyvale, CA (US); Andrew John Lohn, Mountain View, CA (US)

(73) Assignee: THE REGENTS OF THE UNIVERSITY OF CALIFORNIA, Oakland, CA (US)

(21) Appl. No.: 14/345,944

(22) PCT Filed: Sep. 20, 2012
(86) PCT No.: PCT/US12/56421

§ 371 Date: Mar. 19, 2014

Related U.S. Application Data
(60) Provisional application No. 61/536,885, filed on Sep. 20, 2011.

(51) Int. Cl. H01L 35/04; H01L 29/06

(52) U.S. Cl. CPC H01L 35/04; H01L 29/0669
USPC 136/212; 257/9

(57) ABSTRACT

The present disclosure provides improved solid-state thermoelectric devices. A thermoelectric architecture referred to as a nanowire composite includes a plurality of intersecting semiconductor nanowires grown on metallic templates that are formed on a non-single crystal substrate. A plurality of nanowire composites form modules used in thermoelectric devices to generate electric power. The thermoelectric devices using these modules may be fabricated more cost effectively and perform better than conventional thermoelectric devices.

### FIELD

The present disclosure relates to a solid-state thermoelectric device. Particularly, but not exclusively, the present disclosure relates to a solid-state thermoelectric device having a plurality of intersecting semiconductor nanowires and a non-single crystal substrate.

### BACKGROUND

Conventional solid-state thermoelectric devices are used to convert thermal energy into usable electric power. These devices are fabricated using single-crystal semiconductor substrates such as high quality silicon or single-crystal bulk semiconductor material such as bismuth antimony telluride. These single-crystal materials include Group IV (e.g., silicon and germanium), Group III-V (e.g., InP and InSb) and Group V-VI (e.g., bismuth antimony telluride). The single-crystal semiconductor substrates and the bulk semiconductor materials can be very expensive in relation to the amount of electricity that the solid-state thermoelectric devices can generate (i.e., $/W). Accordingly, conventional solid-state thermoelectric devices can be cost prohibitive for many applications.

The use of conventional thermoelectric devices can also be limited by the additional costs associated with large-scale fabrication. A conventional solid-state thermoelectric architecture is depicted in FIG. 1. The conventional solid-state thermoelectric architecture 100 includes a single-crystal bulk semiconductor 102 on a single-crystal semiconductor substrate 101. Total electrical energy output scales with device volume, which is limited by the cost and availability of single-crystal bulk semiconductor and substrate materials.

The use of conventional thermoelectric devices can also be limited because of their poor efficiency. This poor efficiency is partly the result of the interplay between electrical and thermal conductance. Conventional thermoelectric devices couple bulk semiconductor materials between two substantially parallel metallic plates through which electrical charge and thermal energy flows. The plates are maintained at different temperatures, causing a temperature gradient. This temperature gradient causes electrons in an n-type semiconductor material (or holes in a p-type semiconductor material) to migrate to the cold metallic plate. This migration is also referred to as diffusion. The diffusion produces an open circuit voltage when the device is not connected to an external circuit.

Consequently, the diffusion of electrons (or holes) generates an electric field in a direction almost perpendicular to the metallic plates. The magnitude of the electric field depends on the distance between the plates, and the distance depends on the thickness of the semiconductor materials. The electric field causes the electrons (or holes) to migrate in a direction that opposes the diffusion. This opposing migration is also referred to as drift. Thus, the electric field causes a drift of electrons (or holes) that limits a short circuit current generated by diffusion when the device is shorted through an external circuit.

An ideal thermoelectric device has high electrical conductivity and low thermal conductivity, to maximize electrical current while preventing thermal shortage that would destroy the temperature gradient. Conventional devices using single-crystal semiconductors have high electrical and thermal conductivity. The heat conduction occurs along the direction of the diffusion as heat and electrical current share an equal travelling path. Reducing thermal conductivity in thermoelectric devices is challenging because the materials used to provide high electrical conductivity also tend to have high thermal conductivity.

Another type of conventional solid-state thermoelectric architecture is depicted in FIG. 2. This thermoelectric architecture 200 includes a plurality of single-crystal semiconductor nanowires 202 (often referred to as one-dimensional or 1-D materials) on a single-crystal substrate 201. Nanowires 202 are vertically aligned on substrate 201. With the assumption that each nanowire possesses physical characteristics comparable to those of a bulk counterpart, maximizing the electric power generated from thermoelectric architecture 200 requires increasing the packing density of nanowires 202 while maintaining the one-dimensional characteristics of the nanowires. However, increasing the packing density of nanowires 202 for a given nanowire diameter decreases their physical separation that ultimately limits the packing density. The packing density and one-dimensional characteristics of nanowires cannot be optimized independently because these factors are interdependent on growth of the nanowires.

### SUMMARY

The present disclosure provides an improved solid-state thermoelectric device. According to an exemplary embodiment, a thermoelectric architecture referred to as a nanowire composite includes a plurality of intersecting semiconductor nanowires grown on metallic templates that are formed on a non-single crystal substrate. A plurality of nanowire composites form modules used in thermoelectric devices to generate electric power. The thermoelectric devices using these modules may be fabricated more cost effectively and perform better than conventional thermoelectric devices.

In particular, the present disclosure provides nanowire composites comprising, a non-single-crystal substrate; a first metallic template formed on the non-single-crystal substrate; a plurality of semiconductor nanowires formed on the first metallic template; and a second metallic template formed on the plurality of semiconductor nanowires, wherein the nanowires are between the first metallic template and the second metallic template. In some embodiments, the first metallic template is directly disposed on the non-single-crystal substrate. In some embodiments, the first metallic template is formed by reactions of multiple thin films deposited on the non-single-crystal substrate, and the multiple thin films comprise or consist of metals and silicon. In some embodiments, the second metallic template is directly disposed on the plurality of semiconductor nanowires. In some embodiments, the second metallic template is formed by reactions of multiple thin films deposited on the plurality of semiconductor nanowires, and the multiple thin films comprise or consist of metals and silicon. In some embodiments, the second metallic template is formed by placing a single metallic thin layer or multiple metallic thin layers on the plurality of semiconductor nanowires. In some embodiments, the first and the second metallic template act as an electrical conductor and a heat conductor. In some embodiments, the first and/or the second metallic templates are able to expand and/or contract in the directions perpendicular to the surface normal. In some embodiments, the plurality of nanowires are formed of single-crystal materials comprising or consisting of one or more of group II-VI, group III-V, group V-VI, and group IV semiconductors. In some embodiments, the plurality of nanowires are undoped, p-type, or n-type semiconductors. In some embodiments, the plurality of semiconductor nanowires intersect to form three-dimensional nanowire networks. In some embodiments, the total cross-sectional area occupied by nanowires is smaller at some point between the metal templates than near one or both metal-nanowire interfaces. In some embodiments, the nanowires are grown by: setting conditions for the nanowires to grow along their long axes; and changing the conditions for the nanowires to grow in a radial direction, such that the nanowires form a nearly continuous film. In some embodiments, a first nanowire composite is stacked onto a second nanowire composite. In some embodiments, a first nanowire composite is stacked upside down onto a second nanowire composite and the substrate is removed from the second nanowire composite. In some embodiments, a first nanowire composite is connected to a second nanowire composite in parallel. In some embodiments, the first nanowire composite and the second nanowire composite are constructed with a plurality of semiconductor nanowires of different kinds. In some embodiments, the nanowire composite is suitable for use in a thermoelectric system for generating electrical energy. In some embodiments, the second metallic template is maintained at a higher temperature than the first metallic template to create a temperature gradient. In some embodiments, the second metallic template is maintained at a lower temperature than the first metallic template to create a temperature gradient.

Also provided by the present disclosure are thermoelectric systems for generating electrical energy comprising, a plurality of nanowire composite modules interconnected to form an annular shaped loop having an inner side and an outer side; an electrical insulator positioned on the inner side of the loop; and conductors affixed to the outer side of the loop to form an open electrical circuit. In some embodiments, each nanowire composite module comprises a plurality of nanowires formed on a metallic template. In some embodiments, the total cross-sectional area occupied by nanowires is smaller at some point between the metal templates than near one or both metal-nanowire interfaces. In some embodiments, the metallic template is disposed on a non-single crystal substrate. In some embodiments, the metallic template is formed by reactions of multiple thin films prepared on the non-single crystal substrate. In some embodiments, the first and/or the second metallic templates are able to expand and/or contract in directions perpendicular to the surface normal. In some embodiments, the plurality of semiconductor nanowires intersect each other to form three-dimensional nanowire network. In some embodiments, the plurality of nanowires are formed of single-crystal semiconductor materials comprising or consisting of one or more of group II-VI, group III-V, group V-VI, or group IV semiconductors. In some embodiments, a portion of the plurality of interconnected nanowire composite modules are n-type, p-type, or undoped. In some embodiments, the inner side is maintained at a higher temperature than the outer side to create a temperature gradient. In some embodiments, hot exhaust from an automobile heats at least part of the inner side. In some embodiments, hot gas, hot liquid or mixture thereof from a heat source heats at least part of the inner side.

### BRIEF DESCRIPTION OF THE DRAWINGS

Exemplary embodiments will now be described with reference to the accompanying drawings, in which:

FIG. 1 depicts a cross section view of a bulk semiconductor on a single-crystal substrate used in a first type of conventional solid-state thermoelectric device.

FIG. 2 depicts a cross section view of vertically aligned semiconductor nanowires on a single-crystal substrate used in a second type of conventional solid-state thermoelectric device.

FIG. 3 depicts a cross section view of a nanowire composite including a plurality of intersecting nanowires formed on a metallic template disposed on a non-single crystal substrate, according to an exemplary embodiment.

FIG. 4 is a graph showing calculated Z(1D)Tₘ plotted as a function of Z(3D)Tₘ for four different packing densities.

FIG. 5 is a graph showing a phonon (i.e., a particle of heat) transmission function for carbon nanotubes.

FIG. 6 is a graph showing current-voltage characteristics of intersecting InP nanowires.

FIG. 7 is a scanning electron microscope (SEM) image of two intersecting nanowires.

FIG. 8 is an SEM image of InP nanowires on an amorphous silicon template layer prepared on an amorphous SiO₂ surface.

FIG. 9 is transmission electron microscope (TEM) images of two types of InP nanowires.

FIGS. 10(a)-(b) depicts a schematic showing a photoconductor built on a nanowire composite and a SEM image of the photoconductor, respectively.

FIG. 11 is a flow diagram showing a method according to an exemplary embodiment.

FIGS. 12A-D depict a series of fabrication process steps for a nanowire composite thermoelectric device according to various embodiments.

FIGS. 13A-D depict a series of fabrication process steps for stacking nanowire composite thermoelectric devices according to various embodiments.

FIG. 14 depicts a cross-section view of an exemplary waste heat recovery system including two types of thermoelectric modules that employ nanowire composites.

FIG. 15 depicts an apparatus used to collect surface photovoltage data.

FIG. 16 is a graph of a measured surface photovoltage, as a function of modulation frequency for seven randomly selected locations on a sample.

FIG. 17 is a graph of a charge density beneath an outer electrode of an apparatus used to collect surface photovoltage data.

FIGS. 18(a)-(l) are SEM images of silicon nanowires grown on silicon substrates.

FIG. 19 depicts X-ray diffraction results for silicon nanowires grown on silicon substrates.

FIGS. 20(a)-(f) are SEM images for silicon nanowires grown on stainless steel substrates.

FIGS. 21(a)-(b) are SEM images of boron-doped silicon nanowires grown on stainless steel substrates.

FIGS. 22(a)-(b) are side-view SEM images of boron-doped and antimony-doped silicon nanowires grown on silicon substrates, respectively.

FIG. 23 shows a diagram for making electrical contact to a plurality of nanowires on a stainless steel substrate.

FIG. 24 depicts a system used for characterizing thermoelectric structures.

FIG. 25 depicts an exemplary embodiment of a thermoelectric characterization system.

FIGS. 26(a)-(c) are current-voltage curves for undoped, p-type, and n-type, respectively, plurality of nanowires on stainless steel substrates.

FIG. 27 depicts measured values for Seebeck coefficient over a range of temperatures, for undoped, n-type, and p-type nanowires on stainless steel substrates.

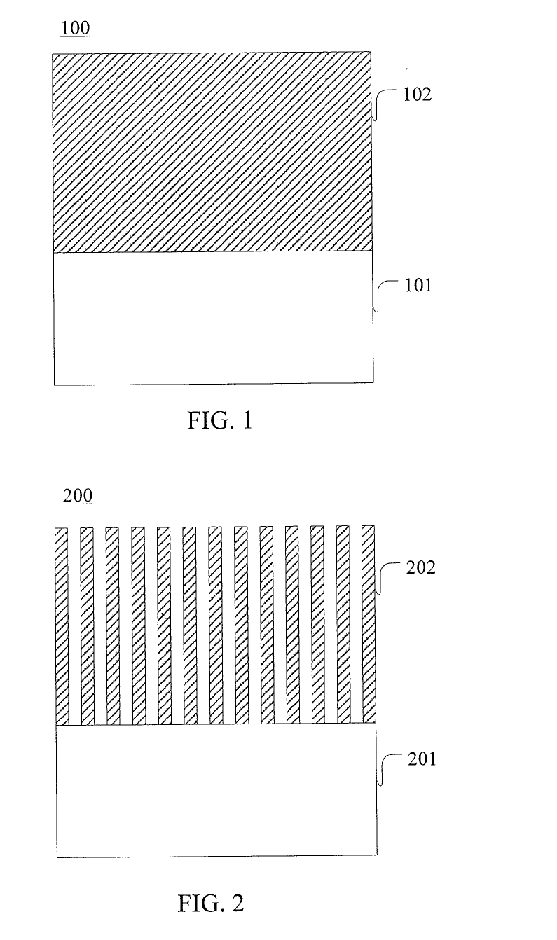

### DETAILED DESCRIPTION

Conventional thinking is to use single-crystal semiconductor substrates to produce high-quality nanowires by a process known as epitaxy, and that using other types of substrates produces low-quality nanowires. The present disclosure provides a novel process for creating high-quality intersecting semiconductor nanowires on non-single crystal substrates. Although the resulting nanowires are not vertically aligned, their intersecting configuration provides superior advantages over conventional thin film and bulk thermoelectric devices. The intersecting nanowires are grown on non-single crystal substrates to form thermoelectric devices with increased energy conversion efficiency while simultaneously minimizing the cost of fabrication including material costs. Accordingly, thermoelectric devices using the intersecting semiconductor nanowires of the present disclosure may be used in a wide variety of applications.

Non-single crystal, as used herein, can mean anything but single-crystal materials (e.g., materials that have a long-range, centimeter, regular atomic arrangement) as understood by crystallographers. For instance, a material that contains small single-crystals embedded in an amorphous matrix is non-single-crystal. A material fully consisting of a large number of small single-crystals is also non-single-crystal. It can include amorphous, microcrystalline, polycrystalline, etc., and the definition should not depend on microscopic structure of a material.

### Nanowire Composites

The thermoelectric devices of the present disclosure are formed from nanowire composites. The nanowire composites have intersecting semiconductor nanowires grown on non-single crystal substrates. The nanowire composites can perform better and cost less than conventional thermoelectric devices.

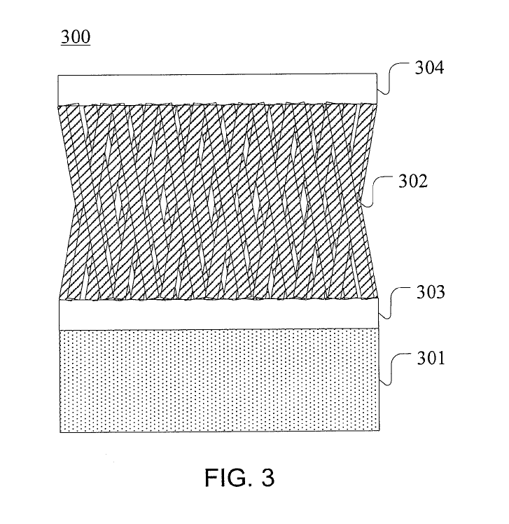

FIG. 3 is a cross section view of nanowire composite 300 including a plurality of intersecting nanowires 302 formed on a metallic template 303 disposed on a non-single crystal substrate 301. A metallic template 303 also acts as an electrode. The plurality of nanowires 302 may be grown using crystal mechanisms of one-dimensional semiconductors on non-single crystal surfaces. For example, SiGe nanowires and Group III-V semiconductors (e.g., InSb, InP) nanowires may be grown on a silicide surface. Silicides are an alloy formed by, for example, solid phase reaction between a transition metal and silicon at high temperatures. Group IV or Group V-VI nanowires may also form plurality of nanowires 302. A second metallic template 304 is formed on top of the plurality of nanowires 302. Metallic template 304 also acts as an electrode. Metallic templates 303 and 304 may be films, plates, layers, or the like, and should be made of a silicide or another type of metallic substance.

The plurality of nanowires 302 provides high electrical conductivity between metallic templates 303 and 304, while also reducing thermal conductivity. A large thermal impedance mismatch between the one-dimensional nanowires 302 and the two-dimensional metallic template host 303 reduces thermal conductivity. In addition, photo scattering at surfaces of the plurality of nanowires reduces thermal conductivity. Electrons in nanowires 302 are confined laterally and thus occupy energy levels that are different from the continuum energy bands in bulk materials. Quantum confinement that modifies the electronic system of nanowires also increases thermoelectric power. Thermoelectric power is also referred to as Seebeck coefficient, which is a measure of the magnitude of an induced thermoelectric voltage of a material in response to a temperature gradient across the material.

The nanowire composite 300 does not require expensive single-crystal substrates or expensive high-quality single-crystal bulk materials, which significantly reduces material costs and increases scalability for high-volume production. In conventional thermoelectric devices that employ nanowires, the highly-structured single-crystal substrate defines the growth of the highly-structured vertically arranged single-crystal nanowires. In contrast, the single-crystal semiconductor nanowires of the present disclosure are not induced to grow in a highly-structured vertical arrangement because the substrate is not made of a single-crystal material. Growth tools such as metal-organic chemical vapor deposition (CVD) may be used for high-volume manufacturing.

Nanowire composite 300 may be used in large-scale implementations for generating electricity from any mechanism that captures or generates heat, such as solar cells or automobiles. Nanowire composite 300 can be effectively used in self-contained vehicles such as submarines, spacecrafts, or the like, because it does not require solar heat to generate electricity.

### Thermoelectric Properties of Nanowire Composites

The thermoelectric properties of nanowire composites provide beneficial performance characteristics over conventional thermoelectric materials. The performance of any thermoelectric materials is characterized by a Figure of Merit, mathematically defined by ZT=Tσα²/κ, where T is temperature, σ is electrical conductivity, κ is thermal conductivity, and a is Seebeck coefficient or thermoelectric power (typically in μV/K).

Ideal thermoelectric materials have high electrical conductivity and low thermal conductivity to prevent thermal shorting, and a high Seebeck coefficient for maximum conversion of heat to electrical power. Higher values of ZT mean higher efficiency and larger amounts of electrical power generated from thermal energy. Conventional thermoelectric devices are limited by low conversion efficiencies, with ZT values around 1.0 or less. Increasing ZT above 1.0 requires identifying materials with high electrical conductivity and low thermal conductivity, and a high Seebeck coefficient.

Semiconductor nanowires provide reduced thermal conductivity and can achieve a ZT much higher than bulk semiconductors. Since a Seebeck coefficient decreases with increasing doping level, a common strategy to increase ZT is to maximize thermoelectric power factor, σα², by doping semiconductors at an appropriate level that leads the product σα² to its maximum.

Semiconductor nanowires are advantageous over bulk semiconductors because of their one-dimensional structure. For example, the electronic density of states of one-dimensional semiconductors is characterized by sharp peaks that enhance thermoelectric power factor, σα², which is not present in bulk semiconductors. As referred to herein, the density of states describes the number of states per interval of energy at each energy level that are available to be occupied. Phonon transport can be significantly suppressed in one-dimensional semiconductors, resulting in smaller lattice thermal conductivity than bulk semiconductors.

The packing density of nanowires partly determines energy conversion efficiency in thermoelectric power generation. Packing density is the ratio of total volume occupied by all nanowires in a device to nominal device volume. Thermoelectric devices using a plurality of nanowires must have a high ZT because packing density cannot be 100% while maintaining one-dimensional characteristics. The intersecting nanowires of the present disclosure can increase packing density while simultaneously maintaining the characteristics of one-dimensional semiconductors.

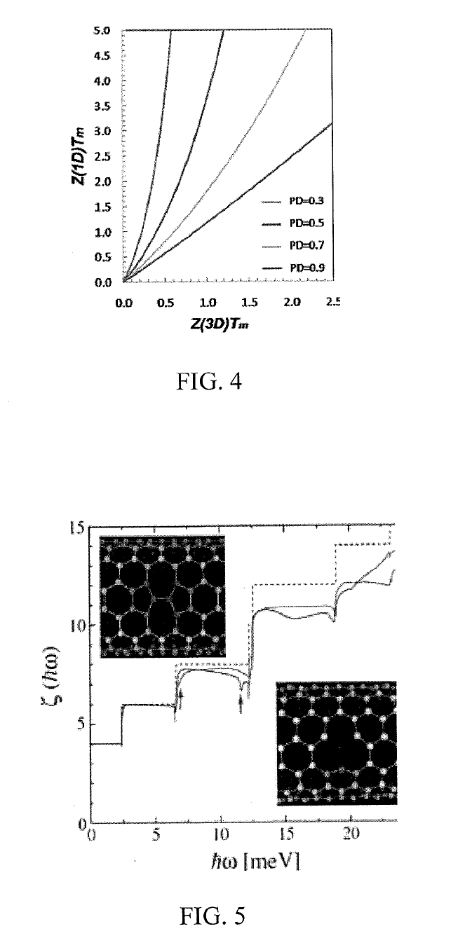

Increasing ZT by implementing nanowires does not automatically provide more electric power for a given thermal input. The ZT required for a plurality of nanowires, Z(1D)Tₘ for a given ZT of bulk semiconductor material, Z(3D)Tₘ for the condition that two Carnot efficiencies obtained by Z(1D)Tₘ and Z(3D)Tₘ are the same with Tₘ=(T_{H}+T_{L})/2, where T_{H} and T_{L} are high and low temperatures, respectively, that create a temperature gradient. FIG. 4 shows calculated Z(1D)Tₘ plotted as a function of Z(3D)Tₘ for four different packing densities (PD). A plurality of nanowires with a packing density up to 70%, which includes nearly all configurations of vertically aligned nanowires, is unlikely to match the ZT of bulk semiconductor materials (e.g., in FIG. 4, Z(1D)Tₘ needs to be higher than 4.5 to match Z(3D)Tₘ=2.0 for PD=70%). Therefore, as described herein, having nanowires intersect, in contrast to conventional nanowires being vertically aligned, ensures that the packing density be maximized without hampering one-dimensional characteristics of nanowires.

Modeling electrical and thermal transport properties of semiconducting nanowires is part of optimization. Landauer formalism is one way to express transport coefficients in terms of well defined microscopic quantities. For example, the electron part of thermal current in the presence of temperature gradients is:

$${J}_{el} = \frac{1}{h} {\int }_{- ∞}^{∞} d E ( E - μ ) [ f ( E , {T}_{L} ) ] {T}_{el} ( E ) \qquad ( 1 )$$

where h is the Planck constant, f(E,T) is the Fermi distribution function, T_{L} and T_{R} are the temperatures of left (hot) and right (cold) reservoirs, respectively, μ is averaged chemical potential, and Tₑₗ(E) is the electron transmission function. The electron contribution to thermal conductance can be obtained using Eq. (1) as:

$${K}_{e} ( T ) = {J}_{el} / ( {T}_{L} - {T}_{R} ) = \frac{2 {k}_{B}}{h} {\int }_{- ∞}^{∞} d {E ( \frac{E - μ}{{k}_{B} T} )}^{2} \frac{{e}^{( E - μ ) / {κ}_{B} T}}{{( {e}^{( E - μ ) / {κ}_{B} T} + 1 )}^{2 }} {T}_{el} ( E ) \qquad ( 2 )$$

where k_{b} is the Boltzmann constant, and T is the average temperature such that T=(T_{L}+T_{R})/2>>T_{L}−T_{R}. The electrical conductance can be expressed through the same transmission function in a similar way:

$${G}_{e} = \frac{2 {e}^{2}}{h} {\int }_{- ∞}^{∞} d E \frac{{e}^{( E - μ ) / {κ}_{B} T}}{{k}_{B} {T ( {e}^{( E - μ ) / {κ}_{B} T} + 1 )}^{2}} {T}_{el} ( E ) \qquad ( 3 )$$

To account for the phonon (i.e., a particle of heat) component of thermal conductance, f(E,T) is replaced with the Bose distribution, and Tₑₗ(E) is replaced with its phonon analog Tₚₕ(E), which yields:

$${K}_{p h} ( T ) = \frac{{k}_{B}^{2} T}{h} {\int }_{- ∞}^{∞} d x \frac{{x}^{2} {e}^{x}}{{( {e}^{x} - 1 )}^{2}} {T}_{p h} ( {k}_{B} Tx ) \qquad ( 4 )$$

where x is a dimensionless parameter defined as x=hω/k_{b}T. Both electron and phonon transmission functions can be expressed through the microscopic non-equilibrium Green's functions and self-energies:

Tₚₕ(E)=Tr[Im(Σ_{L}(E))G(E)Im(Σ_{R}(E)G(E)] (5)

where G(E) is the retarded phonon Green's function of the scattering region and Σ_{L(R)}(E) is the self-energy due to the left (right) lead region. The electron transmission function can be calculated similarly, but the corresponding phonon Green's function and the self-energies must be replaced with their electron analogs.

For an ideal nanowire, each acoustic mode in Eq. (4) contributes a universal quantum K₀=π²k_{B}²T/3h to thermal conductance, which is also found in dielectric mesoscopic wires. A microscopic theory based on Eqs. (4) and (5) can be applied to calculating thermal conductance of carbon nanotubes with structural defects. A typical behavior of the transmission function for a few nanometer long carbon nanotubes is shown in FIG. 5. Notably, the frequency dependence of the transmission function is step-like due to consecutive switching of additional phonon channels in an ideal nanotube. FIG. 5 shows a phonon transmission function for the carbon nanotubes.

Although Eqs. (2) through (5) are a basis for the present disclosure, a broader definition of the electron and phonon transmission functions may account for dissipation effects when the phonon or electron mean-free-path Lₚₕ₍ₑₗ₎ is comparable with the length of sample L. That is, when both the Sharvin and the bulk-type resistances are important. For example, in a one dimensional conductor with width W and length L, in general, two types of “electrical” charge transport are defined: diffusive and ballistic, depending on the magnitude of W and L, as well as the electron mean free path mfp. When mfp<W, it is “diffusive” as Maxwell calculated (Drude resistance). When mfp>>W, it is “ballistic” as Sharvin calculated (Sharvin resistance). When another dimension of a wire, L, is considered, the transition from the Sharivin resistance to the Drude resistance occurs over the range from mfp>>L to mfp<<L. Accordingly, this task may require a combination of both microscopic and semi-empirical, or even purely phenomenological, approaches. Several known models may be used, such as combining first-principle electronic structure calculations with the Boltzmann equation to calculate electrical resistance of magnetic multi-layers. Another model assigns phenomenological relaxation times to each mode of a long silicon nanowire to calculate thermal conductivity.

If dissipation effects due to multiple scattering are incorporated in the transmission functions of Eqs. (2) through (4), then corresponding resistances contain both the ballistic terms known as the Sharvin resistances and the bulk-scattering terms that depend on the mean-free paths L_{ph (el)}. The physics of multiple scattering in a relatively long quantum constriction is known, and this disclosure concentrates on phonon thermal conductance and assumes a step-like transmission function. Eq. (4) is transformed as:

$${K}_{p h} ( T ) = \frac{{k}_{B}^{2} T}{h} {\sum }_{i} \frac{{x}_{i}^{2} {e}^{{x}_{i}}}{{( {e}^{{x}_{i}} - 1 )}^{2}} {T}_{p h}^{( 0 )} ( {k}_{B} {Tx}_{i} ) ( {x}_{i + 1} - {x}_{i} ) \frac{{L}_{p h}^{( i )}}{{L}_{p h}^{( i )} + L} \qquad ( 6 )$$

where Lₚₕ⁽ⁱ⁾(Lₚₕ⁽ⁱ⁾+L)⁻¹ provides for multiple scattering effects in iₜₕ channel. The length of a wire is L, and Lₚₕ⁽ⁱ⁾ is of the order of phonon mean-free path Lₚₕ. For a wire of a sufficiently large cross-sectional area A, quantization of the transverse modes may be ignored and transform sum in Eq. (6) into an integral, since integration can be used instead of summation as a system changes from one that has discrete nature to one that has continuous nature. Further, assume Lₚₕ⁽¹⁾; Lₚₕ for all i and adopt the Debye model:

Tₚₕ⁽⁰⁾(k_{B}Tx)→(AhvₛnT²/k_{B}Θ_{D}³)x² (7)

where vₛ is the speed of sound, n is atomic number density, and Θ_{D} is the Debye temperature. Eqs. (6) and (7) can be used to recover an expression for Debye thermal conductivity κₚₕ=(L/A)Kₚₕ(T)=(⅓)cᵥvₛLₚₕ in the limit of L>>Lₚₕ. In an intermediate regime, however, thermal resistance Kₚₕ⁻¹ is a sum of the Sharvin and the bulk-like terms.

Thus, nanowire composites allow for modifying intrinsic material properties: thermal conductivity, electrical conductivity, and Seebeck coefficient.

### Growing Nanowires on a Metallic Template

The plurality of intersecting nanowires 302 are grown on a metallic template formed on a non-single-crystal substrate. The metallic template may be made of any inexpensive materials such as copper foils, stainless steel foils, alloys, or the like. The materials preferably have very low resistance and are robust at high temperatures. For example, silicide may be a suitable material.

A plurality of nanowires may be synthesized on a metallic template through fine pores created within anodic oxidized aluminium thin films by using various solution based techniques. Solution based techniques include electrochemical deposition which is convenient for synthesizing materials generally characterized by high ionic properties. However, it is challenging to use solution based techniques to grow Group IV and Group III-V semiconductor nanowires which inherently provide a high ZT.

Group III-V semiconductor nanowires are grown on non-single-crystal substrates using a novel approach that couples nanowire growth with a semiconducting template. For example, InP nanowires may be formed on a hydrogenated-microcrystalline silicon (mc-Si:H) template prepared on various non-single-crystal substrates.

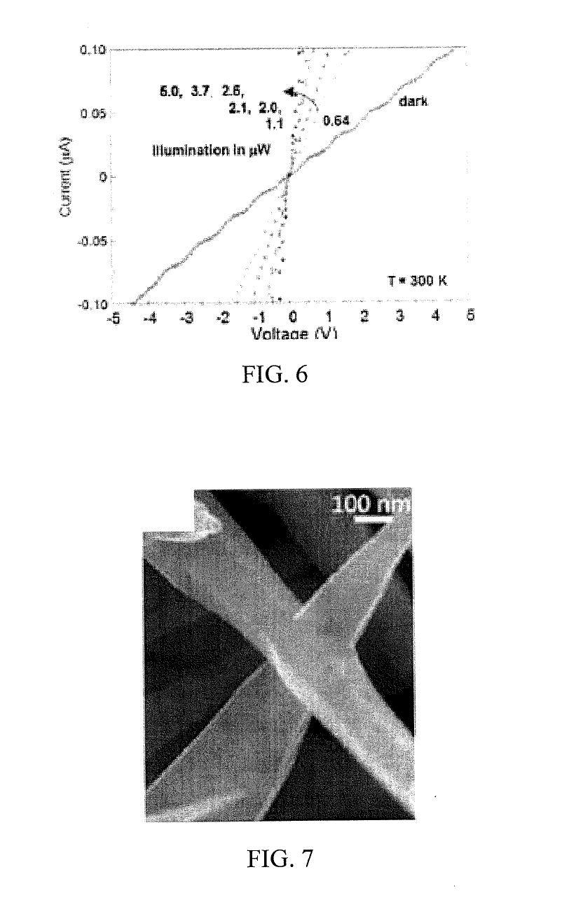

FIG. 6 is a graph showing current-voltage characteristics of intersecting InP nanowires. The current increases as light illumination increases because the excitation of InP nanowires increases.

FIG. 7 is a scanning electron microscope (SEM) image of intersecting nanowires. The intersection forms an electrical connection between the two nanowires.

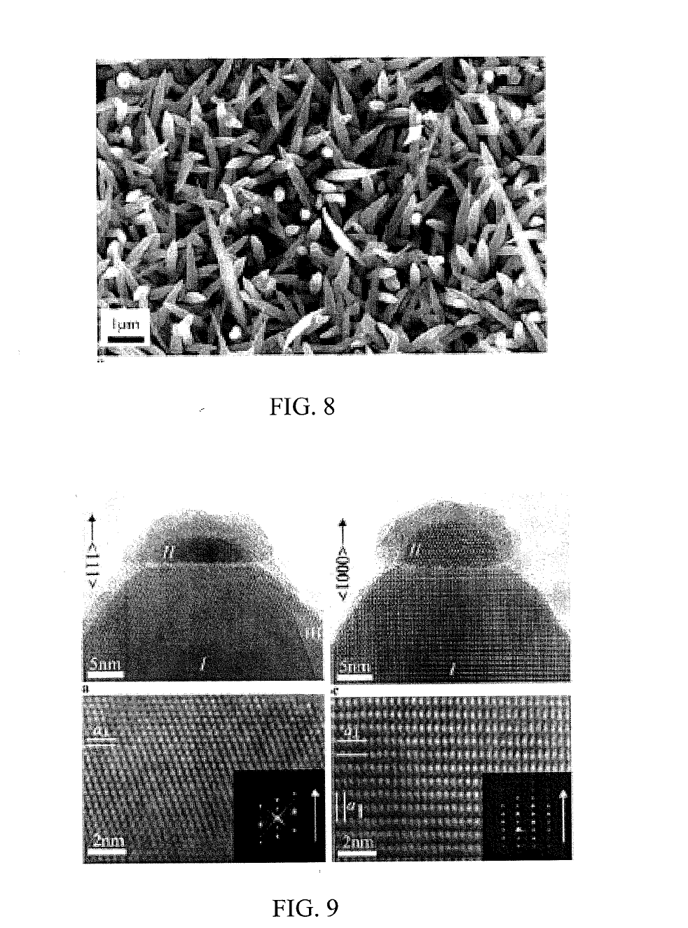

FIG. 8 shows an SEM image of a plurality of intersecting InP nanowires on an amorphous silicon template prepared on an amorphous SiO₂ substrate. The random orientation of the nanowires indicates the lack of atomic order on the metallic template.

FIG. 9 shows transmission electron microscope (TEM) images collected from a tip of a single InP nanowire. The left image shows f.c.c. lattice InP nanowires, and the right image shows h.c.p lattice InP nanowires. The nanowires are single-crystal, optically active, and synthesized on non-single-crystal surfaces. These images show that single-crystal semiconductors can be grown on non-single-crystal substrates.

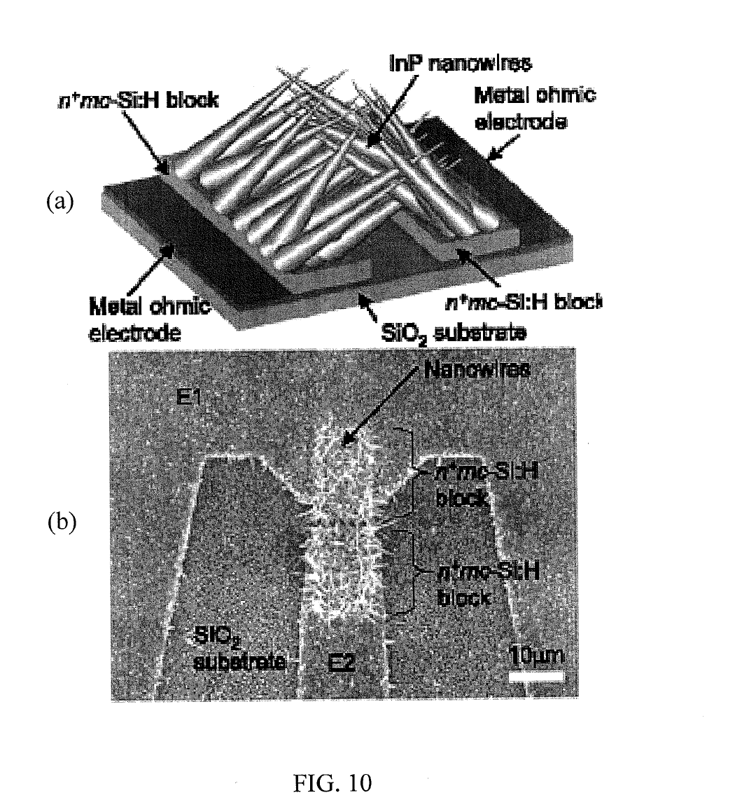

FIG. 10(a) depicts a diagram of a photoconductor built on a nanowire composite. FIG. 10(b) is an SEM image of the photoconductor. This confirms that InP nanowire ultra-high speed photodiodes can be built on non-single crystal substrates. Thus, a plurality of nanowires formed on non-single-crystal substrates can be used for thermoelectric devices.

### Fabricating Nanowire Composites

Fabricating nanowire composites optimizes performance and cost simultaneously because expensive single-crystal substrate materials or bulk semiconductors are not required, yet high-quality semiconductor nanowires with high electrical conductivity, low thermal conductivity, and high Seebeck coefficient can be produced.

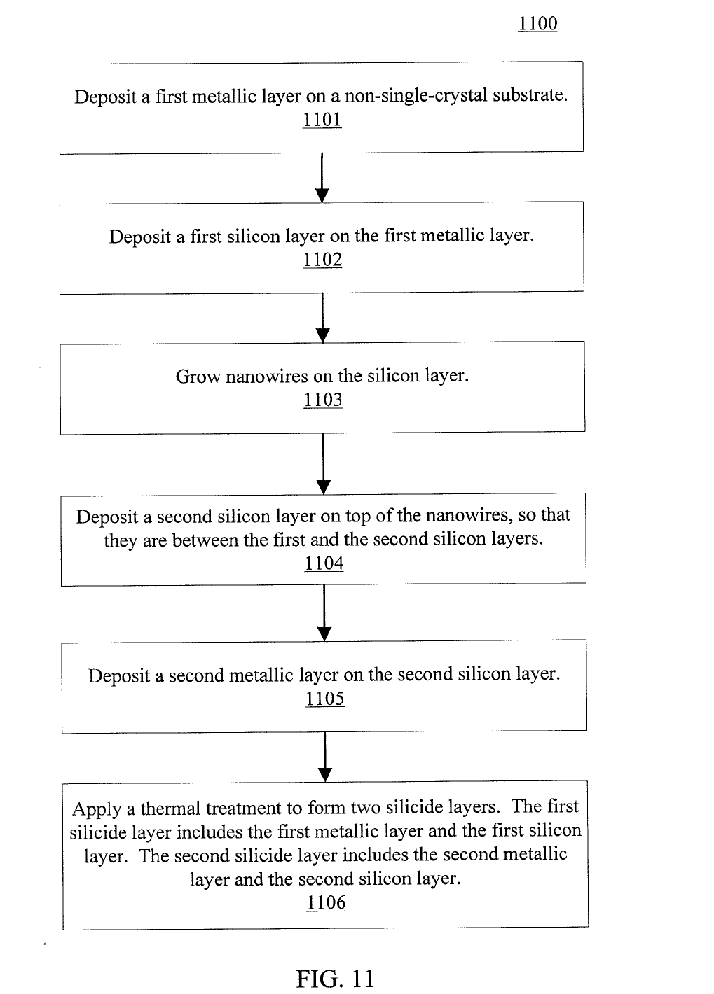

FIG. 11 depicts a flow diagram 1100 for fabricating a nanowire composite. A metallic layer is deposited on a non-single-crystal substrate in 1101. The deposition may occur in a vacuum. A silicon layer is deposited on the metallic layer in 1102. In 1103, nanowires are grown on the silicon layer. In another embodiment, nanowires can be grown on stainless steel surfaces. In one embodiment, as nanowires are grown on the silicon layer, the silicon layer and the underlying metallic layer react to form a silicide layer. In another embodiment, a silicide is formed from a metallic layer and a silicon layer before the growth of nanowires. The nanowires are induced to grow laterally under certain temperature conditions. The nanowires are then induced to grow axially (i.e., in their radial direction) by changing at least the temperature conditions. A plurality of nanowires is formed. The cavities between nanowires may be filled with a substance with very low thermal conductance and electrical conductance, such as plastic, glass, or an insulator. For example, an organic solvent liquid glass may be poured onto the nanowires. The structure having cavities filled with liquid glass can then be heated to drive out any remaining organic solvents.

Another silicon layer may be deposited on top of the plurality of nanowires in 1104, such that the nanowires are coupled between the silicon layers. A second metallic layer may be deposited on the top silicon layer in 1105. Finally, in 1106, a thermal treatment is applied to the nanowire composite to form two silicide layers, above and below the nanowires. Each silicide layer includes a metallic layer and a silicon layer. In another embodiment, a single layer or multiple layers of metal is deposited on top of the plurality of nanowires.

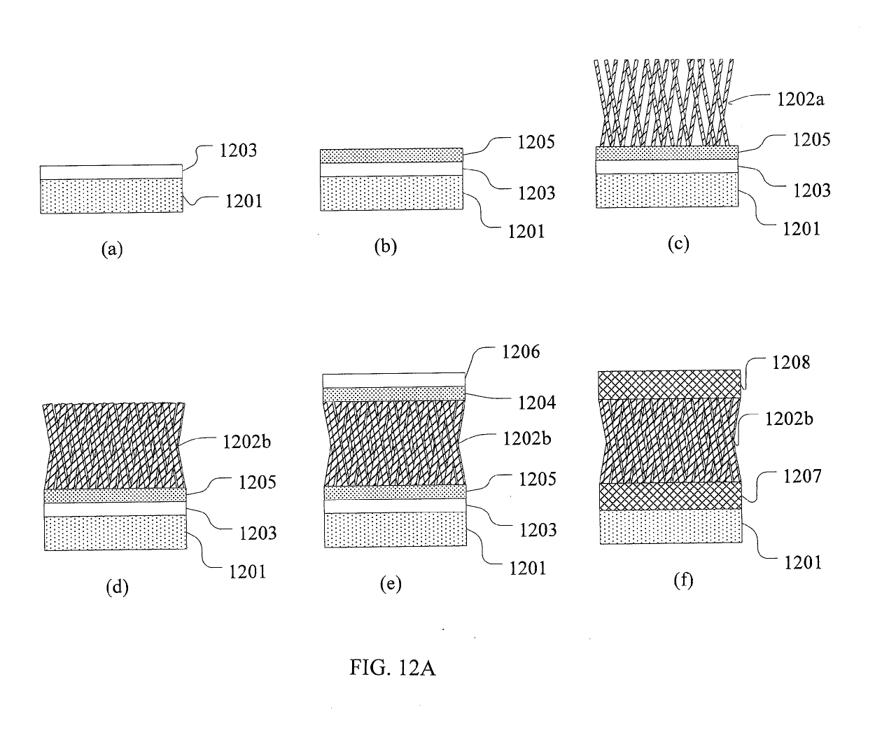

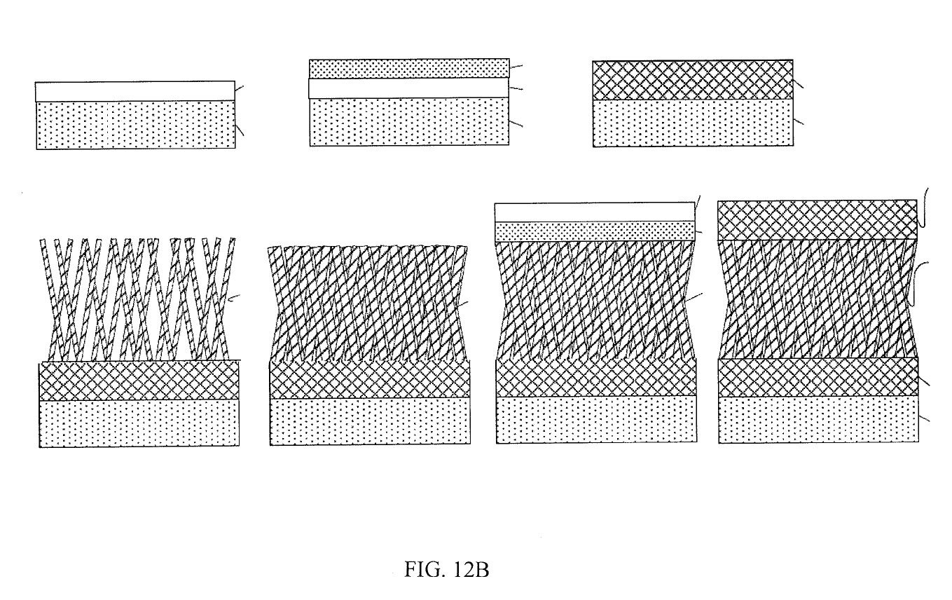

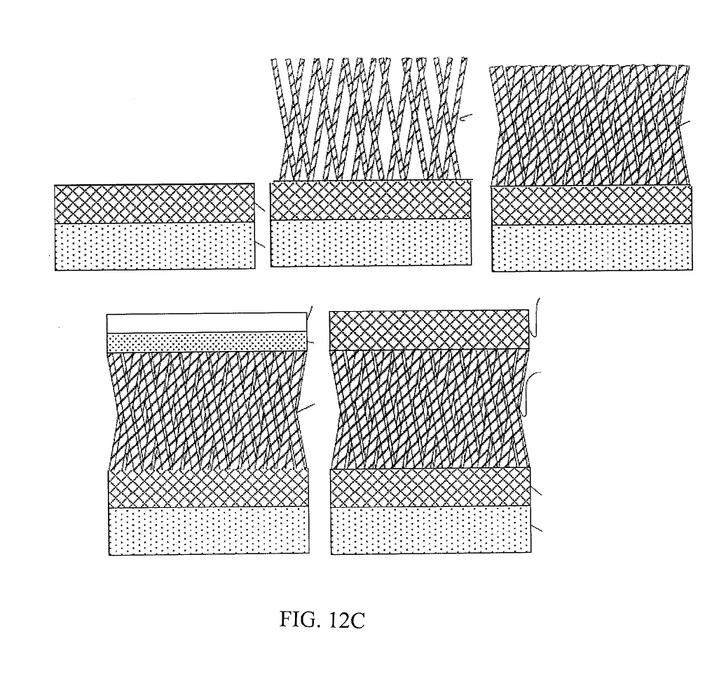

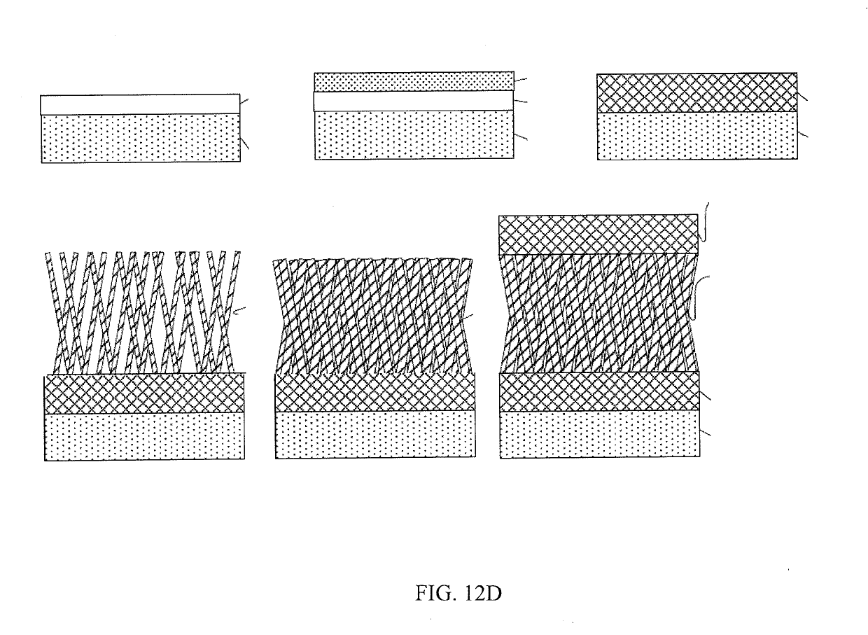

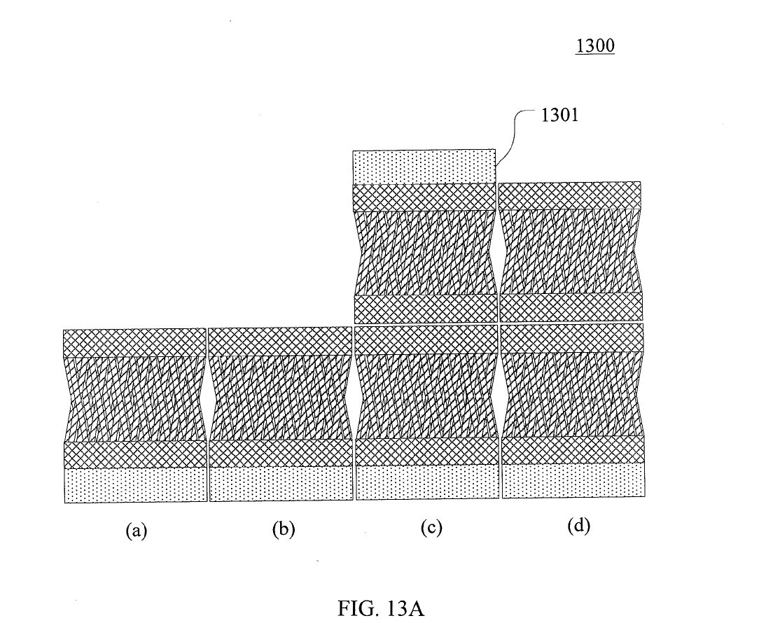

FIGS. 12A(a)-(f) depict the structural fabrication steps of a nanowire composite. In FIG. 12A(a), non-single crystal substrate 1201 is covered by metallic film 1203. Silicon layer 1205 is deposited on metallic template 1205 in FIG. 12A(b), and semiconductor nanowires 1205a are induced to grow laterally on silicon layer 1205 in FIG. 12A(c). Nanowires 1202a begin to form semiconductors that may intersect. Nanowires 1202a in FIG. 12A(c) are induced to grow in a radial direction to form a plurality of nanowires 1202b in FIG. 12A(d). In FIG. 12A(e), silicon layer 1204 is formed on the plurality of nanowires 1202b, and metallic film 1206 is formed on the silicon layer 1204. A thermal treatment is applied to form silicide layers 1207 and 1208. Silicide layer 1208 can be further coupled with a metal electrode. FIGS. 12B-12D illustrate some variations from the structural fabrication steps of FIG. 12A.

### Stacking Nanowire Composites

Nanowire composites are also stackable and reliable. Stackable refers to having nanowire composites stacked on top of each other to increase physical thickness. Reliable refers to having nanowires that are not structurally continuous, but are mechanically flexible when subjected to high-low temperatures during operation as components of thermoelectric devices.

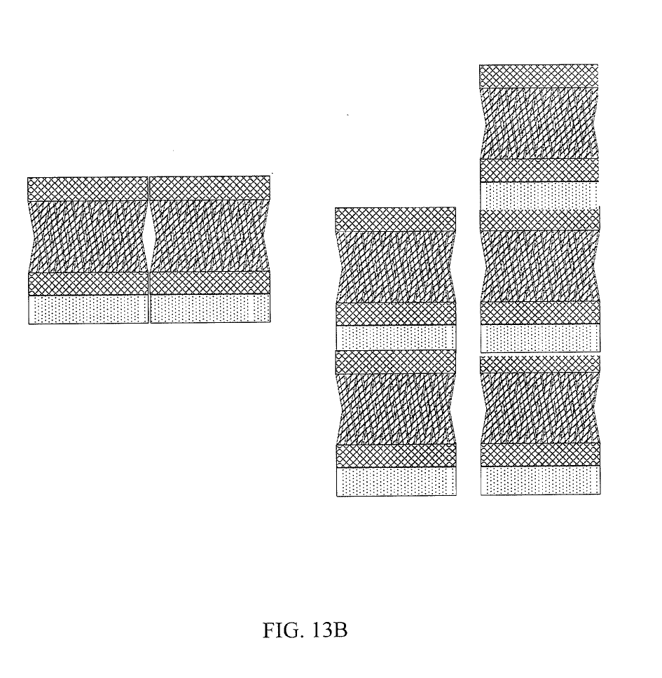

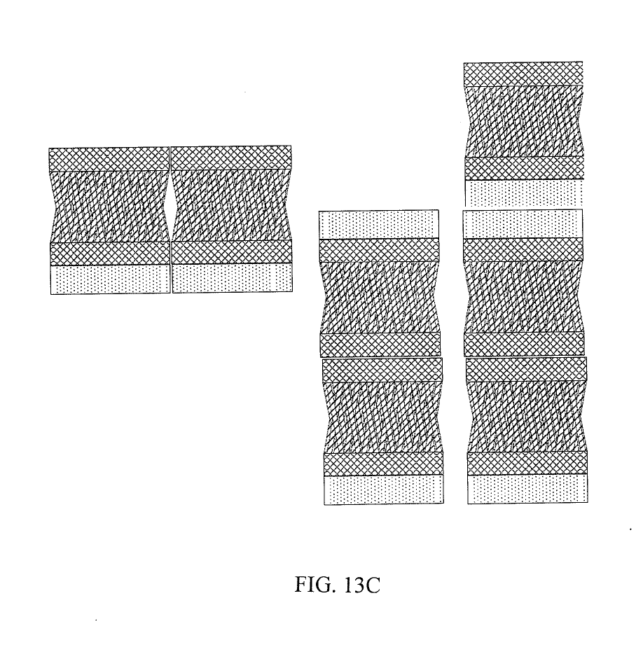

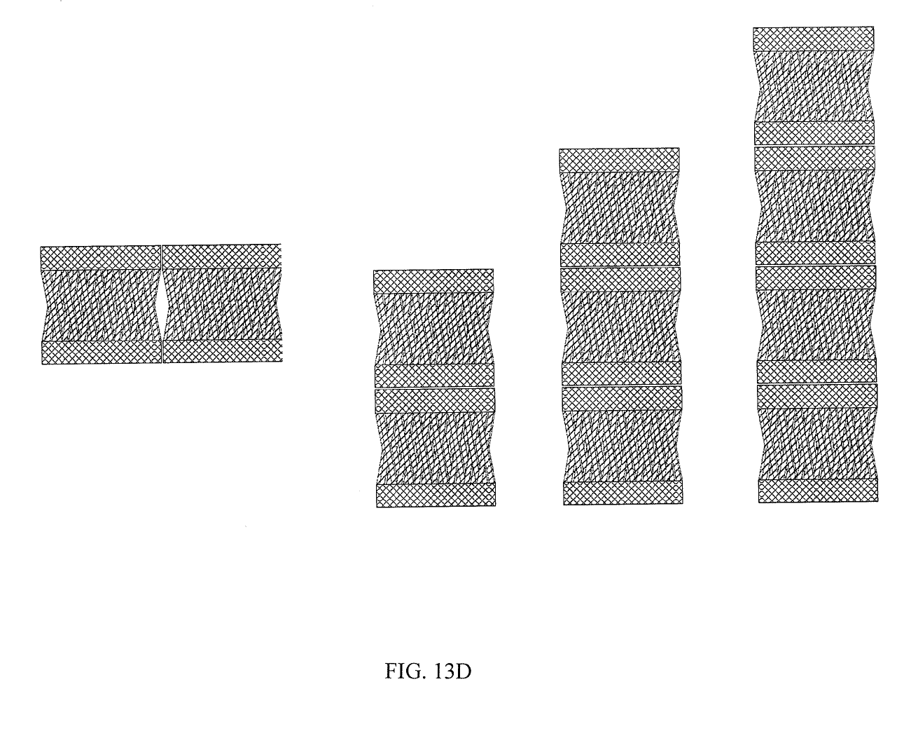

FIGS. 13A(a)-(d) depict fabrication steps to stack nanowire composites. Nanowire composites are formed in FIG. 13A(a) and FIG. 13A(b). Nanowire composite FIG. 13A(a) can be stacked upside-down on nanowire composite FIG. 13A(b) to form stacked nanowire composite FIG. 13A(c), where substrate 1301 of nanowire composite FIG. 13A(a) is removed in FIG. 13A(d). Nanowire composites can be repeatedly stacked on top of each other, then pasted or bonded together by using a bonding technique. FIGS. 13B-13D illustrate some stacking variations from FIG. 13A.

Stacking can be advantageous because it can provide for easily fabricating very thick semiconductors for improved electrical power generation. Another advantage to stacking is that growing longer nanowires requires more time while stacking nanowire composites, which may have shorter nanowires, provides the same effect as thicker semiconductors with longer nanowires. Stacking can provide for flexible structures that can be shaped around a heat source, such as the exhaust pipe of an automobile. Any cavities between adjacently stacked nanowire composites may be filled with insulating materials to ensure structural integrity while maintaining the conductive properties of the plurality of nanowires. The filling substance may be similar to that described above for filling the cavities between nanowires.

### A Waste Heat Recovery System

The nanowire composites of the present disclosure may be interconnected to form thermoelectric power generation modules for thermoelectric devices. The modules may be formed on flexible substrates to produce thermoelectric devices of any shape, suitable for using heat energy from many waste heat producing systems, such as automotive exhaust systems.

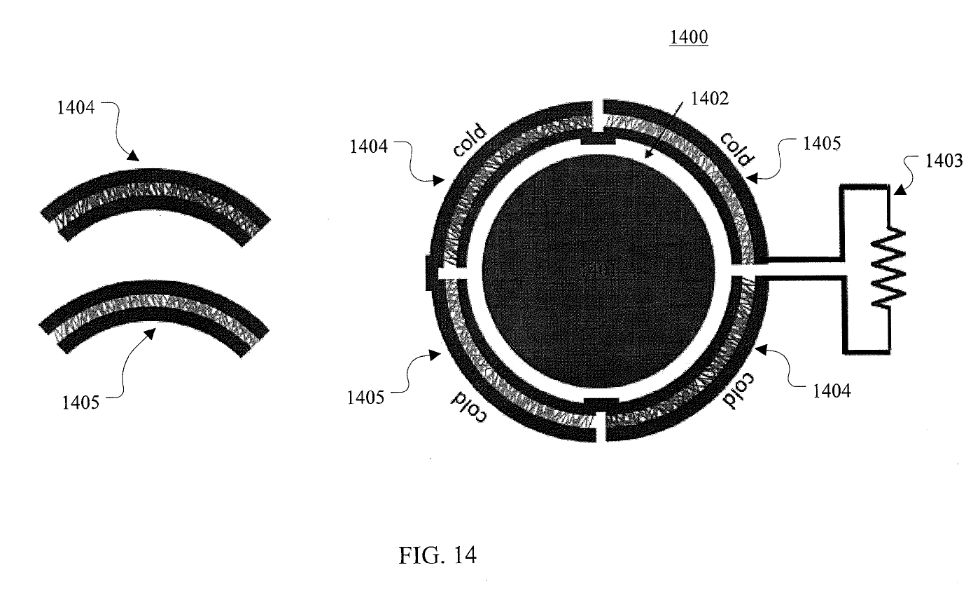

FIG. 14 depicts a cross section view of an exemplary waste heat recovery system 1400 including two types of thermoelectric modules employing nanowire composites. The two types of modules include n-type nanowire modules 1404 and p-type nanowire modules 1405. The heat recovery system 1400 includes alternating n-type 1404 and p-type 1405 modules interconnected to form an open-loop circuit around a heat source 1401. The heat source 1401 may be an exhaust pipe of an automobile on which the waste heat recovery system 1400 is attached. The inside of the loop may include an insulator 1402 that ensures a good thermal contact between the heat source 1401 and the modules 1404 and 1405 and prevent the modules 1404 and 1405 from electrical shortage from each other. An electrical circuit 1403 is formed by connecting electrodes of the nanowire modules to a load to complete a current.

### Reduction of Drift Resulting in the Increase in Open Circuit Voltage

An advantage of the present disclosure is that a plurality of intersecting nanowire composites as shown in FIG. 3 can reduce the drift current impeding the diffusion current. Each device is made of interconnected nanowire composites having a plurality of nanowires between two metallic templates. One metallic electrode is maintained at an elevated temperature above the other, to create a temperature gradient. Electrical charge flows through the plurality of nanowires. Electrons in n-type nanowires (or holes in p-type nanowires) diffuse to the cold side, resulting in an electrical open circuit voltage appearing on an external circuit between the two metallic templates.

The structure of the intersecting nanowires reduces the drift that opposes the desired diffusion of electrons to the cold metallic template. The long-axis of the nanowires is not perpendicular to the two metallic templates, which means that the electric field generated by the diffusing electrons (or holes) is not necessarily perpendicular to the metallic plates. Further, the intersecting nanowires form fused nodes at intersections that provide multiple paths for electrons (or holes) to travel in different directions. The changing directions of diffusing electrons (or holes) create many electric field vectors that cancel out to reduce drift, when compared to conventional thermoelectric devices. Thus, a smaller total drift that opposes diffusion increases open circuit voltage.

The intersecting nanowires can also provide reduced thermal conductivity because of the fused nodes created by the intersecting nanowires. The nodes disrupt heat conductance as the phonon mean free path is larger than the mean distance between two nodes but not electron transport because the electron mean free path is much shorter than the mean distance between two nodes. From a quantum mechanical point of view, heat and electrons have specific wavelengths and the wavelength associated with heat conduction is much longer than that associated with electrons. Thus, a plurality of intersecting nanowires disrupts heat flow but does not reduce the diffusion of electrons (or holes) to generate a more efficient thermoelectric device.

### Stability in Hetero-Materials Interfaces

Thermoelectric power generation modules should be stable at high temperatures. Factors that contribute to the overall stability of power generation modules include the stability of their hetero-interfaces and the overall integrity of the modules. A hetero-interface is an interface where two dissimilar materials are thermally and electrically coupled.

The mechanical robustness of a hetero-interface at high temperatures, below the melting points of the materials that make the interface, depends on many factors. A mismatch in thermal expansion coefficients between dissimilar materials governs the robustness of their interface when the inter-diffusion between them is ignored. Thermal expansion is a material property associated with non-linear characteristics of the displacement of atoms with respect to their equilibrium positions.

Among various hetero-interfaces shown in FIG. 14, two important hetero-interfaces are between the electrical insulator 1402 and the electrode (on the hot side) of modules 1404 and 1405, and between exhaust pipe 1401 and electrical insulator 1402. These are ceramic-metal interfaces.

Employing an interface with continuously changing chemical compositions, also known as a graded interface, is a conventional way to join two materials having different thermal expansion coefficients. However, changing the chemical compositions of solid materials used in thermoelectric devices within a wide range of temperatures is not practical and is cost prohibitive for large-scale applications.

Eutectic systems may be used as “glue” between a ceramic and a metal. A eutectic system is a mixture of chemical compounds or elements that has a single chemical composition that solidifies at a lower temperature than any other composition. For example, two elements, for example, Pb and Sn, can be mixed to form a Pb—Sn alloy. The melting point of Pb and Sn is 327 and 2320 C, respectively. The melting temperature of Pb—Sn alloys depends on the composition (i.e., the volume ratio of Pb to Sn). A eutectic system, such as the Pb—Sn alloy, has a special composition, 61.9% Sn for instance, at which the melting point is minimum (for instance, 1830 C for 61.9% Sn of Pb—Sb system). Thus, it is possible to take advantage of the low melting point of a eutectic system to bond two materials. A wide range of eutectic systems with various eutectic temperatures can be used for different types of interfaces.

### Passivation for High Temperature Stability

Effective surface passivation can be important for nanowire composites based on thermoelectric materials that provide peak energy conversion efficiencies at temperatures near their melting points. Passivation is a coating that protects a surface of a semiconductor so that a semiconductor does not decompose at elevated temperatures. Passivation also stops a surface of a semiconductor from being contaminated with foreign elements from environment.

Peak energy conversion efficiency is associated primarily with the band gap of a thermoelectric material. In solid-state physics, a band gap, also called an energy gap, is an energy range in a solid where no electron states can exist. At higher temperatures, intrinsic minority carriers that are thermally excited contribute to a reduction in thermoelectric power (i.e., Seebeck coefficient). Nanowire materials provide a large Seebeck coefficient and they have low dependence on Seebeck coefficient with temperatures between 20 to 80° C., which makes them suitable for low-temperature thermoelectric applications. The energy conversion efficiency of thermoelectric materials at temperatures above and below their peaks degrades so much that performance at those temperatures may not be important to the overall design of thermoelectric devices. The band gaps of semiconductor materials, SiGe and Group III-V compounds, can be tuned to maximize ZT at a wide range of temperatures found in many waste heat producers, such as automobiles. For example, for a semiconductor A having a bandgap at the energy Ea, there is a corresponding optimum temperature Eopt-a at which ZT takes the maximum. In contrast, the bandgap of alloy semiconductors AB can be tuned in general between Ea and Eb. Therefore, Eopt-ab can be also tuned within a certain range, offering a wider tuning range in terms of the optimum operation temperature.

Surface passivation of nanowire composites can eliminate the decomposition of constituent elements at high temperatures. Notably, nanowires made of Group IV and Group III-V semiconductors are structurally stable, with the exception of their large surface areas, which results in a large surface to volume ratio. Thus, passivation of nanowires is critical for making nanowire composites chemically robust at high temperatures.

Atomic layer deposition (ALD), which is a deposition mechanism that relies primarily upon reactions that occur on the surface of a substrate exposed to the gas phase that contains deposition precursors, can be used for passivating the three-dimensional topological features created by a plurality of nanowires. Various ALD processes for a wide-range of surfaces are available on metals as well as on ceramics.

ALD processes can be designed at low temperatures (˜250° C.) by relying on self-limiting surface chemical reactions of precursors that contain desirable chemical elements. Thus, thermal mechanical stress during an ALD process and residual mechanical stress in nanowire composites can be minimized. Many metal oxides, including aluminium oxide and zirconium oxide are chemically stable on semiconductor surfaces and may be used on surfaces of Group IV, Group III-V, and Group V-VI semiconductor nanowires to stabilize the surfaces of nanowires.

### Resistance at Interfaces of Dissimilar Materials

Electrical resistance at interfaces employing nanowire composites for thermoelectric devices can be reduced to increase thermoelectric efficiency. Some thermoelectric devices, particularly those used in automotive applications, have multiple interfaces between metallic and thermoelectric materials. These types of devices are subject to a wide range of temperatures, and resulting temperature gradients. Low electrical contact resistance at interfaces where two dissimilar materials meet can reduce parasitic electrical losses in thermoelectric devices. Generally, thermoelectric conductance cannot be reduced even when reducing electrical resistivity, if there is high electrical contact resistance at interfaces between metal electrodes and thermoelectric materials.

Chemically treating the tips of nanowires may provide low contact resistance between the nanowires and metallic template electrodes, to achieve contact resistances of about 10⁻⁷ Ω·cm² over a wide range of temperatures. At high temperatures, there are several factors that impact contact resistance. For example, reactions between contact metallization and thermoelectric materials should be well managed. Forming silicide between nanowires and metallic template can ensure low contact resistance at high temperatures to increase thermoelectric efficiency.

### A Thermoelectric Characterization System

A novel vacuum-insulated chamber for measuring thermoelectric properties of nanowire composites and modules that have device architecture substantially different from thin-film thermoelectric devices is disclosed herein. A three-dimensional model for electrical and thermal conductance in nanowire composites, at a module-level, may be used to optimize module design.

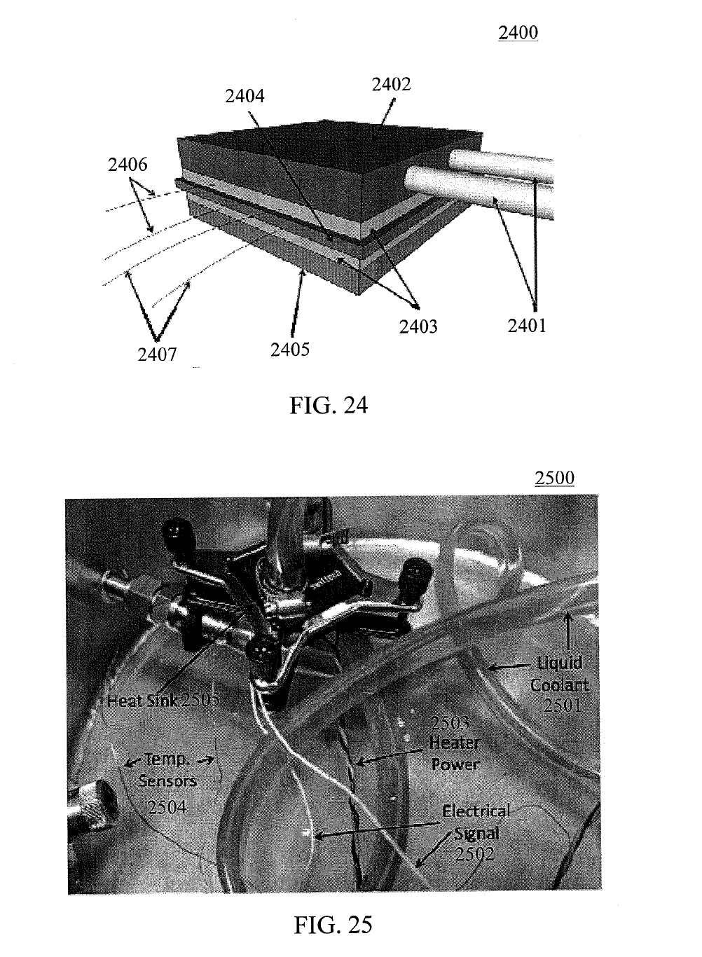

FIG. 24 depicts a schematic of the thermoelectric characterization system 2400 used for nanowire based thermoelectric devices. Heat flows from a heater 2405 to a liquid cooled heat sink 2402 through copper contacts 2403, and to the thermoelectric device being tested 2404. The liquid coolant is provided via channels 2401. Embedded electrodes 2407 and temperature sensors 2406 in the copper contacts 2403 allow for measuring Seebeck coefficient, electrical conductivity, and thermal conductivity.

FIG. 25 depicts an exemplary embodiment of a thermoelectric characterization system. The thermoelectric characterization system 2500 is mounted in a vacuum chamber. The thermoelectric characterization system has a heat sink 2505 and electrical wiring inside the vacuum chamber. The vacuum chamber reduces heat transfer from convection by bypassing the thermoelectric device being tested. Heat power 2503 is provided to the liquid cooled heat sink 2505. Liquid coolant is provided via channels 2501. Electrodes 2502 and temperature sensors 2504 are embedded in the copper contacts to measure Seebeck coefficient, electrical conductivity, and thermal conductivity.

TABLE 1 below includes a summary of thermoelectric characterization results for a plurality of silicon nanowires on stainless steel substrates that were measured using the thermoelectric characterization system.

TABLE 1
Summary of thermoelectric characterization results for
silicon nanowire arrays on stainless steel substrates.

| Sample | Seebeck Coefficient | Electrical Conductivity |
|---|---|---|
| Undoped | +400 | 1.5 × 10⁻¹⁰ Ω⁻¹cm⁻¹ |
| p-type | +50 | 4.5 × 10⁻⁶ Ω⁻¹cm⁻¹ |
| n-type | −50 | 4.2 × 10⁻⁵ Ω⁻¹cm⁻¹ |

Seebeck coefficient can be determined with a high degree of certainty by using the thermoelectric characterization system. The electrical conductivity can be improved by optimizing the interface between a plurality of silicon nanowires and the top metallic electrode.

### AC Surface Photovoltage of Nanowires

Surface photovoltage (SPV) is a tool for characterizing various properties of nanowires for thermoelectric devices. The large surface to volume ratio for nanowires makes understanding various effects associated with their surfaces important for optimizing the design of nanowire composites for thermoelectric devices.

SPV may be used to determine the dynamics of carrier transport through a plurality of intersecting nanowires described in this disclosure, over large distances (˜5 mm). The nanowires can have a charge transport over distances in excess of their lengths, which is a substantial difference from those that occur in conventional single or multiple independent nanowires. SPV may be measured within a region 10.5-14.5 mm from the focus of a light illumination, between a range of frequencies from 15 Hz to 30 kHz. The dynamics of photo-generated carriers may be modeled by treating the plurality of intersecting nanowires as a thin film. This model suggests that diffusion mobilities of electrons and holes are approximately 75% of those in bulk semiconductors, but with significantly reduced electric fields.

For example, a plurality of InP nanowires grown on amorphous substrates provides a three-dimensional nanowire-network with long-range carrier transport from one nanowire to another. Thermoelectric devices based on a nanowire composite consisting of a three-dimensional network of nanowires provide the added functionality of electrical and thermal transport in directions nominally perpendicular to the surface of the substrate where the nanowires are grown.

### Nanowire Growth for Thermoelectric Devices

Thermoelectric devices may be based on SiGe or InP nanowires, or the like. The semiconductor nanowires can be grown on low-cost, electrically conductive substrates by different processes. An SiGe system may be preferred because of its low-cost and abundance.

The epitaxial template for growth of InP nanowires may be fused silica substrates covered with 200 nm thick films of hydrogenated micro-crystalline silicon (μc-Si:H). Gold nanoparticles suspended in toluene with diameters of approximately 10 nm are dispersed on the μc-Si:H template layer to catalyze nanowire growth via a vapor-liquid-solid (VLS) mechanism. Nominally undoped InP nanowires may be grown by CVD, metal-organic chemical vapor deposition (MOCVD), plasma-enhanced chemical vapor deposition (PECVD), or the like, in a vertical cold-wall reactor using various precursors such as trimethylindium, tertiarybutylphosphine, and phosphine.

The resulting intersecting nanowires have high density with large aspect ratios at approximately 50-100 nm in diameter and 10 μm in length. The nanowires intersect each other to form a three-dimensional network (i.e., the core part of the nanowire composite defined herein) and provide an electrical path for carriers to flow over distances in excess of the length of any single nanowire. With nanowire densities sufficiently high and lengths adequately long, the bond density, defined as the number of electrical interconnections per unit volume, exceeds the percolation threshold and a continuous electrical path extends across the entire sample, which can be an advantage. The percolation threshold is a mathematical term related to percolation theory, which is the formation of long-range connectivity in random systems.

This disclosure also provides processes for growing doped and undoped silicon nanowires. Growth rates may be high, on the order of 10 minutes to produce 100 μm long nanowires, at temperatures around 500° C. Nanowires may be single-crystals in the [111] direction defined as a notation used in a conventional cubic crystal structure, with morphologies tailored by growth and doping conditions. A large Seebeck coefficient can be measured for undoped silicon nanowires deposited by CVD, which have low dependence on Seebeck coefficient with temperatures in the range of 20 to 80° C.

### SPV Measurement and Quantification

Although quantitative models exist to extract many parameters of interest from SPV data for conventional bulk semiconductors and thin films, these models rely on simplifying assumptions such as an infinite sample thickness and a quasi-neutral region beneath the space charge region, which are not valid for nanowire networks in nanowire composites.

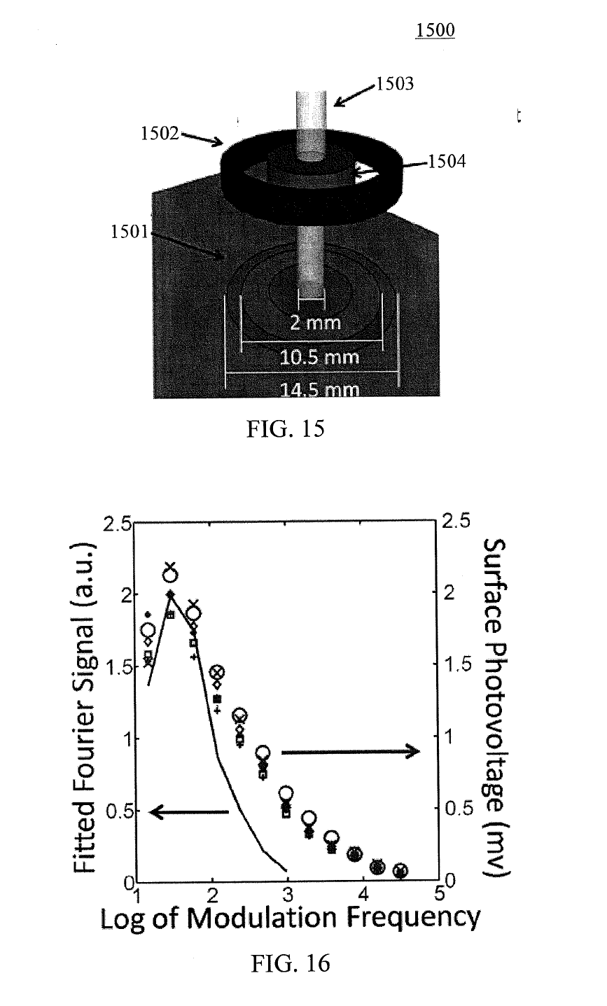

FIG. 15 depicts an apparatus used to collect SPV data of nanowire networks. The apparatus 1500 takes measurements at room temperature. Two concentric electrodes are held about 500 μm above the nominal surface of the nanowire network. The outer electrode 1502 surrounds the inner electrode 1504. The inner electrode 1504 has an inner diameter of 10.5 mm. The outer electrode 1502 has an outer diameter of 14.5 mm. An SPV signal from the outer electrode is collected at random locations on the surface of the nanowire network 1501. A modulated excitation light 1503 is focused on an illumination area that is 2 mm in diameter, through the inner electrode 1504. The modulated excitation light 1503 may have a wavelength of 520 nm and power of about 500 μW/cm². The modulated excitation light 1503 has a 50% duty cycle at a range of frequencies from 10 Hz to 30 kHz, which can be sent to a lock-in amplifier for data collection.

To quantify SPV measurements, the transport of photo-generated charges through an InP nanowire network can be modulated. For a first-order approximation, an InP nanowire network may be modeled as a continuous InP film with equilibrium carrier density comparable to that expected for the network. The inhomogeneous diffusion equation is solved for diffusion currents by using an implicit finite differences method, with Shockley-Reed-Hall recombination and time and space-dependent carrier generation.

The electric field due to photo-generated electrons and holes may be computed at incremental time-steps where drift currents are added to diffusion currents. The computation proceeds for several cycles, until carrier densities at all positions on the sample are approximately equal to their values from a previous cycle. Carrier density over a range of 10.5-14.5 mm is then averaged as a function of time for a single modulation cycle. A Fourier transformation is performed on the resulting carrier densities, expressed in time domain, to determine the magnitude of carrier density oscillations occurring at a specific modulation frequency (MF).

The magnitude of charge density oscillations at an MF is proportional to SPV. The diffusion and drift mobilities for electrons and holes are varied separately to find the best fit for the experimental SPV data. The best fit is often obtained with diffusion mobilities at approximately 75% of the bulk semiconductor values for InP, and with built-in potentials much weaker than those found in bulk semiconductors. Mobilities in μc-Si:H are approximately 4-5 orders of magnitude lower, eliminating the possibility that the signal is originating in the template layer. The reduced built-in potential is from nanowire surface potentials in directions not perpendicular to the substrate.

### SPV Data Collected

SPV data was collected at seven randomly selected locations on a sample, and are shown as a function of MF in FIG. 16. FIG. 16 also shows the computed Fourier signal normalized to the peak of SPV data. SPV data and the Fourier signal both show increasing magnitude from 15 Hz to 30 Hz, then decrease with increasing MF, which shows a peak. Excess electrons (or holes) generated by above-band gap excitation cause fluctuations in surface potential as they redistribute in the space charge region.

Fluctuations in surface potential are caused by electrical potential resulting from separation of electrons and holes. An increase in SPV at low frequencies occurs as the SPV signal becomes sinusoidal, resulting in a larger percentage of the SPV signal at the MF. For example, at 60 Hz, the percentage of the SPV signal at the MF is equally large. However, the decreasing magnitude of the charge density oscillations causes a decreasing SPV. Further increases in MF result in decreases in charge density oscillation magnitude and in SPV.

Despite the inherent complexity of nanowire networks, the SPV signals collected are consistent, as evidenced by small distributions for a given MF in FIG. 16. Thus, SPV in nanowire networks develops in a predictable way that is independent of inherent structural randomness. Numerous electrical paths exist between the illumination area and the outer electrode 1502 with a distribution of path lengths that could contribute to a slower decay of a measured signal as compared to a calculated signal.

The quantitative assessment of SPV data for nanowire networks may be approximated as a continuous thin film. Qualitatively, large differences between electron and hole diffusion mobilities can result in electron and hole densities that substantially vary in both space and time, as a function of MF. FIG. 16 depicts the variation of a calculated transient carrier density at the outer electrode 1502 plotted as a function of both percent of elapsed time, within a single modulation cycle and MF. At low MF, there are large oscillatory features in carrier density that decrease in peak-to-peak magnitude with increasing MF.

At low frequencies, there is a steady-state carrier distribution at the outer electrode 1502 when the rate of incoming electron flow is balanced with the rate of recombination. At the lowest frequency of 15 Hz, the steady-state carrier distribution begins to flatten at approximately 20% of the modulation cycle and extends toward the midway point of the cycle prior to the end of the illumination period (50% duty cycle).

As electrons and holes are generated in the illuminated region of the apparatus used to collect surface SPV 1500, the electrons quickly diffuse away because they have larger diffusion mobility than holes, and travel toward the outer electrode 1502. This creates an excess of electrons flowing beneath the outer electrode 1502 and leaves an excess of holes near the illuminated region. Hole densities beneath the outer electrode 1502 decrease from their equilibrium density due to recombination with excess incoming electrons. Once the illumination is turned off, the photo-generated holes near the illuminated region continue to diffuse outward, which results in a flow of holes beneath the outer electrode 1502.

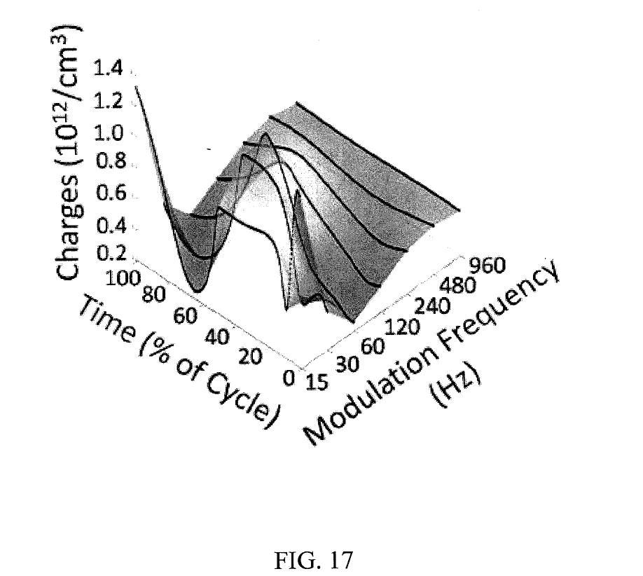

The steady-state carrier distribution is maintained for a smaller percentage of the modulation cycle with increasing MF, which causes the rounded peaks for MF at 30 and 60 Hz in FIG. 17. Above a MF of 60 Hz, there is a smaller departure from equilibrium and a steady-state carrier distribution is not achieved. Without reaching a steady-state, the peak-to-peak oscillations decrease. At higher frequencies, the timescale of the MF is so short that in diffusion over 5 mm, the modulated optical excitation is like a continuous wave having negligible AC components in the SPV signal.

FIG. 17 depicts the peak-to-peak magnitude of carrier density oscillations that decrease with increasing MF. The decrease is relatively small for frequencies below 60 Hz. However, steady-state is not achieved at higher frequencies, beneath the outer electrode during the excitation phase of a single modulation cycle. This results because of insufficient time for recombination at the outer electrode.

As depicted in FIG. 17, while charge oscillations decrease in peak-to-peak magnitudes from 15 Hz to 30 Hz, the SPV in FIG. 16 increases. This results from a lock-in amplification technique that selects only the component of the SPV signal that is oscillating at the MF. At 15 Hz, a significant portion of the SPV signal is due to spectral components which are different from the MF and therefore do not contribute to the SPV signal. FIG. 17 shows that at frequencies up to 60 Hz, the SPV signal has fewer spectral components, resulting in a larger percentage of the total oscillation being measured by the lock-in amplification technique. FIG. 16 shows results in larger SPV signals and the peak. Modeling the interconnected nanowire network as a thin film enables understanding the origin of the main features of the result depicted in FIG. 16.

Thus, the dynamics of photo-generated carriers that transport through a nanowire network may be examined by using AC SPV. The SPV signal has weak dependence on specific microscopic geometry of intersecting nanowire networks. The electric field generated in response to spatial variations of mobile charge densities in a nanowire network is effectively reduced by the surface potential of the nanowires, which does not occur in a conventional system that contains geometrically aligned nanowires. By using a plurality of intersecting nanowires, electrons and holes travel over distances larger than the length of a single nanowire.

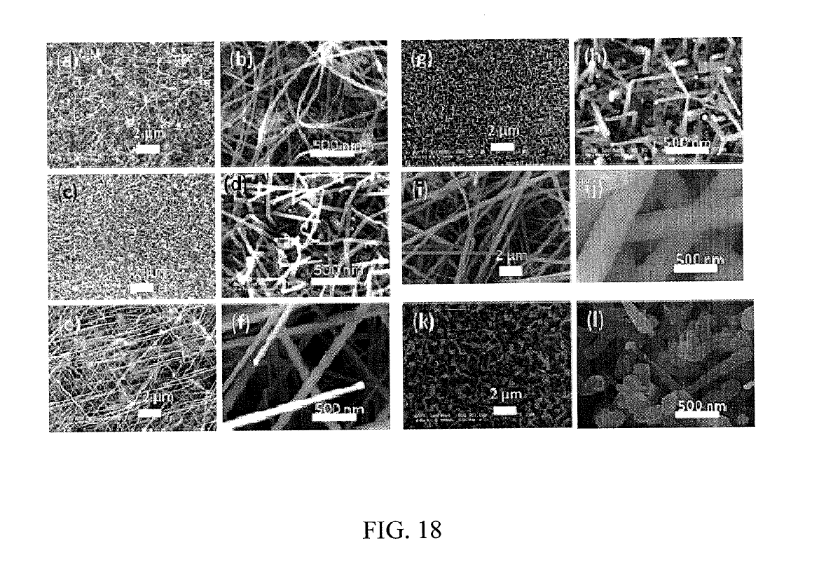

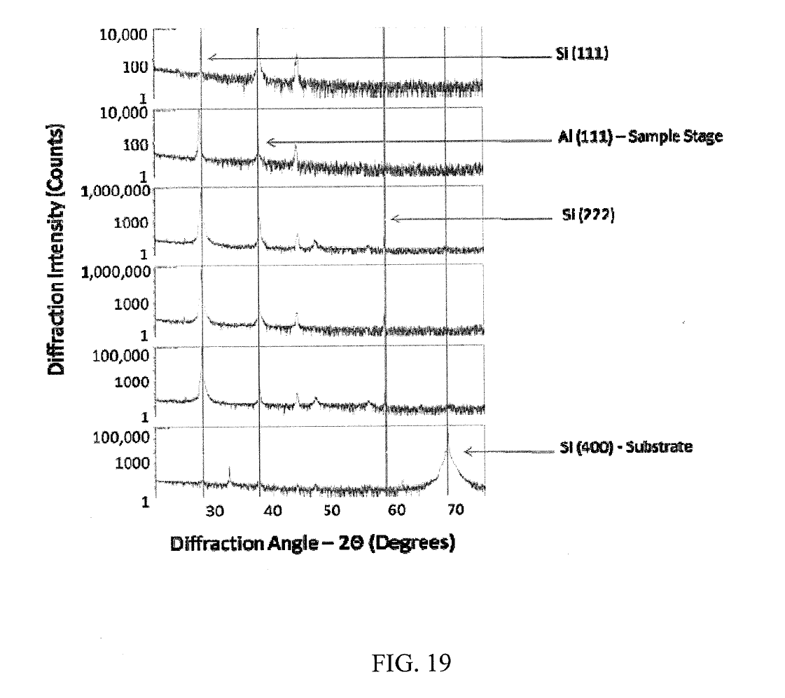

The nanowires may be undoped, n-type doped (Sb or As), p-type doped (B), and p-n doped (B then Sb) for silicon substrates or stainless steel foil substrates. FIGS. 18(a)-(l) are SEM images for silicon nanowires grown on silicon substrates. FIGS. 18(a) and 18(b) are images of undoped nanowires, FIGS. 18(c) and 18(d) are images of arsenic doped nanowires, FIGS. 18(e) and 18(f) are images of boron doped nanowires, FIGS. 18(g) and 18(h) are images of antimony doped nanowires, FIGS. 18(i) and 18(j) are images of boron doped nanowires subsequently doped with antimony, and FIGS. 18(k) and 18(l) are images of undoped nanowires. The morphology of the nanowires is dependent on growth and doping conditions. FIG. 19 depicts x-ray diffraction (XRD) results for silicon nanowires grown on silicon substrates by CVD. The XRD results are for single-crystal silicon nanowires grown in the (111) direction.

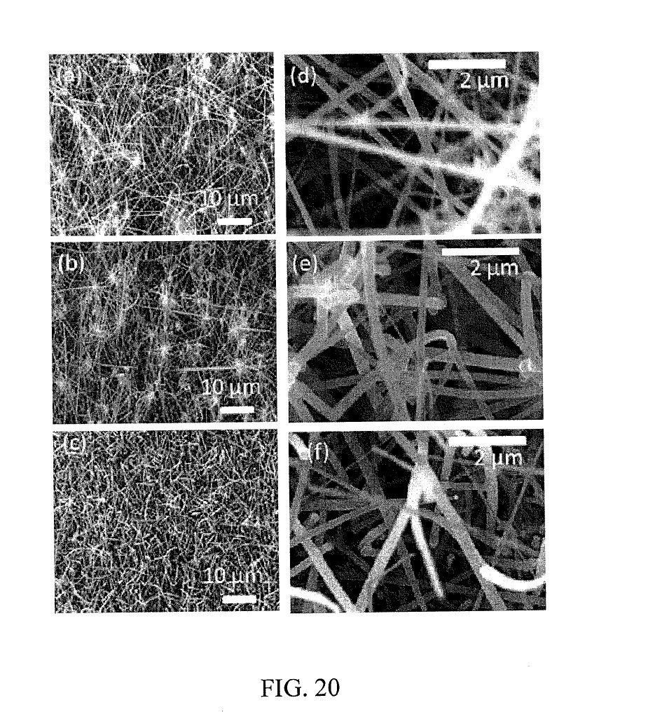

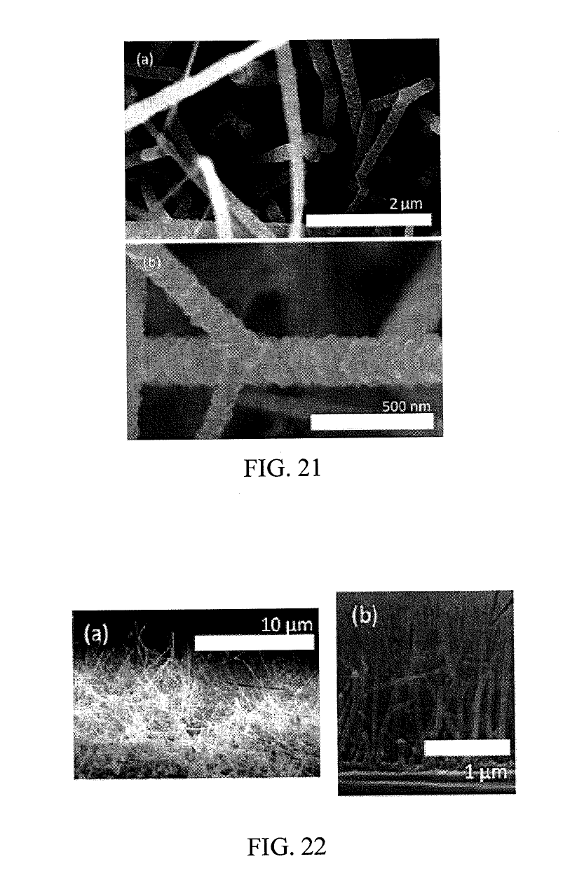

FIGS. 20(a)-(f) are SEM images for silicon nanowires grown on stainless steel substrate. FIGS. 20(a) and 20(d) are images of undoped nanowires, FIGS. 20(b) and 20(e) are images of antimony doped (n-type) nanowires, and FIGS. 20(c) and 20(f) are images of boron doped (p-type) nanowires. Growth of a plurality of intersecting nanowires on low-cost stainless steel substrates can provide suitable platforms for the production of economical devices. FIGS. 21(a) and 21(b) are SEM images of boron-doped (p-type) nanowires grown on stainless steel. Surface roughness may be observed for the as-deposited boron-doped nanowires when grown on steel substrates, but not when grown on silicon. This surface roughness may act to reduce thermal conductivity for nanowires.

The embodiments are not limited to the detailed description given above. Variations are apparent to a person skilled in the art. For example, the waste heat recovery system could be attached to any device or structure providing heat on one side of the nanowire composite modules to create a temperature gradient across the modules. Further, the system could be attached to any device or structure extracting heat on one side to provide a temperature gradient across the module. The system shape could be adapted to suit any kind of situation or location where electrical energy generation is desired. A portable heat recovery system based on nanowire composites could have a flexible structure to adapt to any surface. Examples include using the system on a boat, submarine, airplane, spacecraft, home, office, near a refrigeration or heating unit, and the like.

FIGS. 22(a) and 22(b) are side-view SEM images of boron-doped silicon nanowires grown on a silicon substrate and antimony-doped silicon nanowires grown on a silicon substrate, respectively. Although the morphology can range from primarily vertical alignment to random alignment with many contact points between nanowires, these embodiments utilize nanowires that intersect and form three-dimensional network.

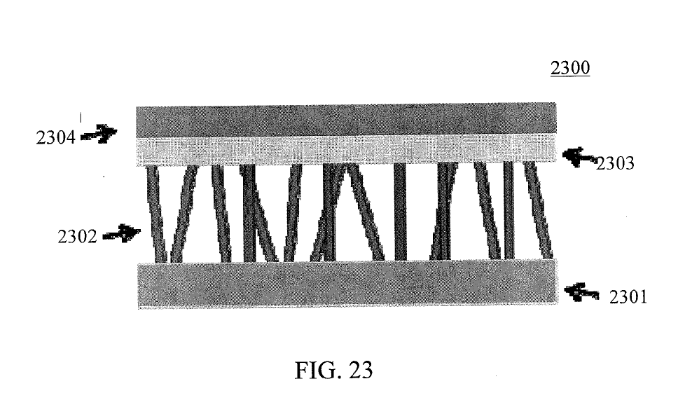

Various techniques for making electrical and thermal contacts to a plurality of nanowires may be used. FIG. 23 shows a diagram for making electrical contact to a plurality of nanowires on a stainless steel substrate. The nanowire composite 2300 makes electrical contact with silicon nanowires 2302 grown on a steel foil substrate 2301. A dielectric insulating layer 2303 may be deposited on nanowires 2302 to provide mechanical support. A top metal contact 2304 may be deposited on the dielectric insulating layer 2303 by evaporation. A sufficient number of nanowires 2302 make electrical contact to the top metal electrode 2304 to make the device operable. The interconnected nature of the nanowires increases fault tolerance by creating redundant electrical pathways. The plurality of nanowires 2302 on steel substrate 2301 may be bonded to rigid substrates.

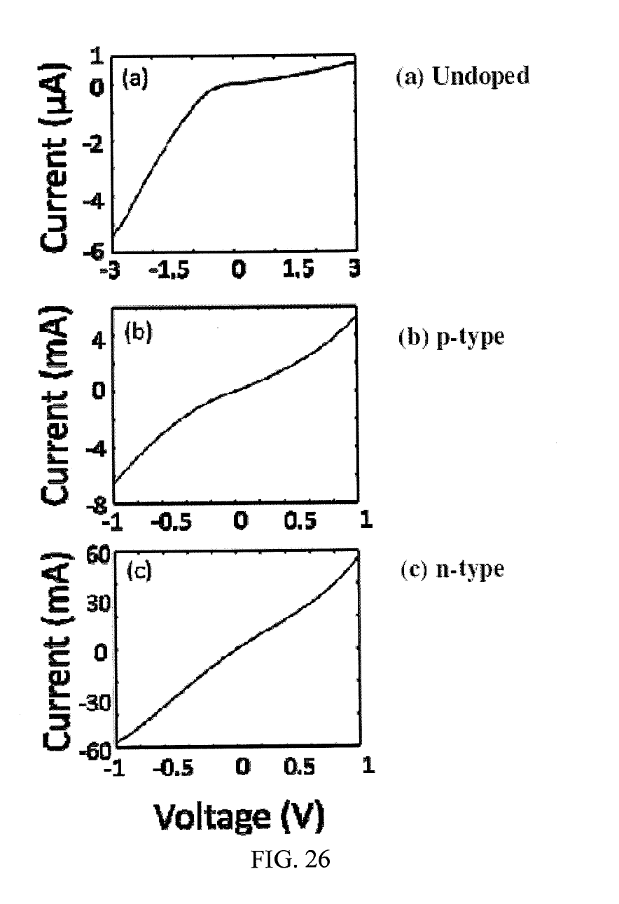

FIGS. 26(a)-(c) are current-voltage curves for a plurality of silicon nanowires on silicon substrates. The curves depict electrical properties of three types of devices: FIG. 26(a) depicts undoped, FIG. 26(b) depicts p-type, and FIG. 26(c) depicts n-type nanowires grown on stainless steel substrates. The rectifying behavior (i.e., asymmetric I-V characteristics with respect to zero voltage) seen in the undoped sample may be due to a weak Schottky barrier that rectifies electrical current at the metal-nanowire interface. With increased doping, the devices are nearly ohmic (perfect resistance).

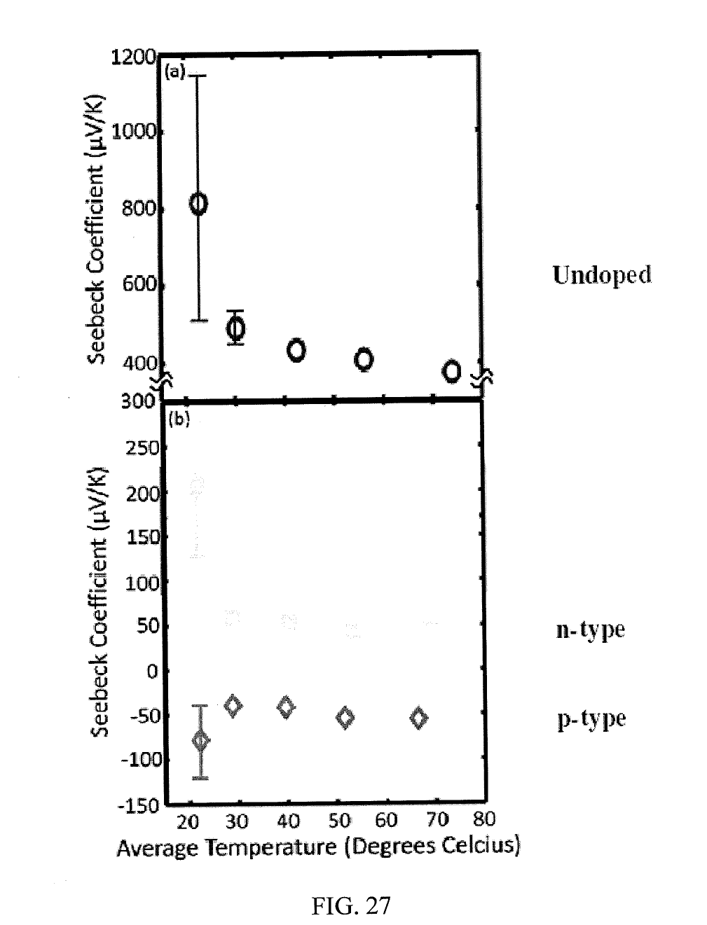

FIG. 27 depicts measured values for Seebeck coefficient over a range of temperatures, for undoped, n-type, and p-type nanowires on stainless steel substrates. Error bars are shown where the error measurement is larger than the data marker. The measurements were done over a range of temperatures within “low-grade heat.” Large Seebeck coefficient (approximately 400 to 800 μV/K) was observed for undoped silicon nanowires, suggesting that a large number of intersecting nanowires that form a three-dimensional nanowire network described in this disclosure has a potential to be a good thermoelectric material. The Seebeck coefficient is relatively insensitive to temperatures in this range, which is advantageous because it often decreases with increasing temperatures, in this range, in conventional bulk semiconductors.

The various embodiments described above have been presented for purposes of illustration and description. They are not intended to be exhaustive or to limit the embodiments to the precise forms disclosed, and obviously many modifications and variations are possible in light of the above teaching.

1. A nanowire composite comprising,
a non-single-crystal substrate;
a first metallic template formed on the non-single-crystal substrate;
a plurality of semiconductor nanowires formed on the first metallic template; and
a second metallic template formed on the plurality of semiconductor nanowires, wherein the nanowires are between the first metallic template and the second metallic template.

2. The nanowire composite of claim 1, wherein the first metallic template is directly disposed on the non-single-crystal substrate.

3. The nanowire composite of claim 1, wherein the first metallic template is formed by reactions of multiple thin films deposited on the non-single-crystal substrate, wherein the multiple thin films comprise metals and silicon.

4. The nanowire composite of claim 1, wherein the second metallic template is directly disposed on the plurality of semiconductor nanowires.

5. The nanowire composite of claim 1, wherein the second metallic template is formed by reactions of multiple thin films deposited on the plurality of semiconductor nanowires, wherein the multiple thin films comprise metals and silicon.

6. The nanowire composite of claim 1, wherein the second metallic template is formed by placing a single metallic thin layer or multiple metallic thin layers on the plurality of semiconductor nanowires.

7. (canceled)

8. The nanowire composite of claim 1, wherein the first and/or the second metallic templates are able to expand and/or contract in the directions perpendicular to the surface normal.

9. The nanowire composite of claim 1, wherein the plurality of nanowires are formed of single-crystal materials comprising one or more of group II-VI, group III-V, group V-VI, and group IV semiconductors.

10. The nanowire composite of claim 1, wherein the plurality of nanowires are undoped, p-type, or n-type semiconductors.

11. The nanowire composite of claim 1, wherein the plurality of semiconductor nanowires intersect to form three-dimensional nanowire networks.

12. The nanowire composite of claim 1, wherein the total cross-sectional area occupied by nanowires is smaller at some point between the metal templates than near one or both metal-nanowire interfaces.

13. The nanowire composite of claim 1, wherein the nanowires are grown by:
setting conditions for the nanowires to grow along their long axes; and
changing the conditions for the nanowires to grow in a radial direction, such that the nanowires form a nearly continuous film.

14. The nanowire composite of claim 1, wherein a first nanowire composite is stacked onto a second nanowire composite.

15. The nanowire composite of claim 1, wherein a first nanowire composite is stacked upside down onto a second nanowire composite and the substrate is removed from the second nanowire composite.

16. The nanowire composite of claim 1, wherein a first nanowire composite is connected to a second nanowire composite in parallel.

17. The nanowire composite of claim 1, wherein a first nanowire composite and a second nanowire composite are constructed with a plurality of semiconductor nanowires of different kinds.

18. (canceled)

19. The nanowire composite of claim 1, wherein the second metallic template is maintained at a different temperature than the first metallic template to create a temperature gradient.

20. (canceled)

21. A thermoelectric system for generating electrical energy comprising:
a plurality of nanowire composite modules interconnected to form an annular shaped loop having an inner side and an outer side;
an electrical insulator positioned on the inner side of the loop; and
conductors affixed to the outer side of the loop to form an open electrical circuit.

22. The thermoelectric system of claim 21, wherein each nanowire composite module comprises a plurality of nanowires formed on a metallic template.

23. The nanowire composite of claim 21, wherein each nanowire composite comprises a plurality of nanowires formed on a metallic template and a total cross-sectional area occupied by nanowires is smaller at some point between the metallic template than near one or both metal-nanowire interfaces.

24. The thermoelectric system of claim 21, wherein each nanowire composite comprises a plurality of nanowires formed on a metallic template and the metallic template is disposed on a non-single crystal substrate.

25. The thermoelectric system of claim 21, wherein each nanowire composite comprises a plurality of nanowires formed on a metallic template and the metallic template is formed by reactions of multiple thin films prepared on the non-single crystal substrate.

26. The nanowire composite of claim 21, wherein each nanowire composite comprises a plurality of nanowires formed on a first metallic template and a second metallic template is formed on the plurality of nanowires, the first and/or the second metallic templates are able to expand and/or contract in the directions perpendicular to the surface normal.

27. The thermoelectric system of claim 21, wherein the plurality of semiconductor nanowires intersect each other to form three-dimensional nanowire network.

28. The thermoelectric system of claim 21, wherein the plurality of nanowires are formed of single-crystal semiconductor materials comprising one or more of group II-VI, group III-V, group V-VI, or group IV semiconductors.

29. The thermoelectric system of claim 21, wherein a portion of the plurality of interconnected nanowire composite modules are n-type, p-type, or undoped.

30.-32. (canceled)
